(19) United States
(12) Patent Application Publication
(10) Pub. No.: US 2024/0329133 A1
(43) Pub. Date: Oct. 3, 2024

(54) System and Method for Utilizing Idle Computing Capacity

(71) Applicant: Tapster Robotics, Inc., Oak Park, IL (US)

(72) Inventor: Jason Randolph Huggins, Oak Park, IL (US)

(21) Appl. No.: 18/620,871

(22) Filed: Mar. 28, 2024

Related U.S. Application Data
(60) Provisional application No. 63/492,829, filed on Mar. 29, 2023.

(51) Int. Cl. G01R 31/3183; G01R 31/317

(52) U.S. Cl. CPC G01R 31/318314; G01R 31/31713; G01R 31/31721

(57) ABSTRACT

The present disclosure relates to systems and methods for utilizing idle computing capacity. One example embodiment includes a system. The system includes a chassis configured to hold a device under test. The system also includes a computing device attached to the chassis. The computing device is configured to receive an input indicative of content being displayed on a user interface of the device under test. The computing device is also configured to determine, according to a predefined workflow, an instruction for the device under test based on the input. Additionally, the computing device is configured to provide the determined instruction to the device under test. The determined instruction is usable by the device under test to interact with a portion of the user interface in a specified way.

### CROSS-REFERENCE TO RELATED APPLICATIONS

The present application is a non-provisional patent application claiming priority to Provisional Patent Application No. 63/492,829, filed Mar. 29, 2023, the contents of which are hereby incorporated by reference.

### BACKGROUND

Computing devices (e.g., mobile computing devices or tablet computing devices) can be used to perform various tasks. For example, a computing device (e.g., with an associated camera) may be used to monitor one or more physical environments (e.g., by capturing and analyzing photos). Additionally or alternatively, a computing device may be used (e.g., by a user) to communicate information (e.g., to another computing device, such as via text message or email). One or more tasks performed by a computing device may be performed through one or more applications (e.g., one or more mobile apps).

### SUMMARY

The specification and drawings disclose embodiments that relate to systems and methods for utilizing idle computing capacity.

In a first aspect, the disclosure describes a system. The system includes a chassis configured to hold a device under test. The system also includes a computing device attached to the chassis. The computing device is configured to receive an input indicative of content being displayed on a user interface of the device under test. The computing device is also configured to determine, according to a predefined workflow, an instruction for the device under test based on the input. Additionally, the computing device is configured to provide the determined instruction to the device under test. The determined instruction is usable by the device under test to interact with a portion of the user interface in a specified way.

In a second aspect, the disclosure describes a method. The method includes receiving, by a computing device, an input indicative of content being displayed on a user interface of a device under test. The device under test is held by a chassis. The computing device is attached to the chassis. The method also includes determining, by the computing device according to a predefined workflow, an instruction for the device under test based on the input. Additionally, the method includes providing, by the computing device, the determined instruction to the device under test. The determined instruction is usable by the device under test to interact with a portion of the user interface in a specified way.

In a third aspect, the disclosure describes a non-transitory, computer-readable medium having instructions stored thereon. The instructions are executable by a processor to perform a method. The method includes determining, according to a predefined workflow, an instruction for a device under test based on an input indicative of content being displayed on a user interface of the device under test. The input indicative of content being displayed on the user interface of the device under test is receivable by the processor. The non-transitory, computer-readable medium and the processor are attachable to a chassis configured to hold the device under test. The method also includes providing the determined instruction to the device under test. The determined instruction is usable by the device under test to interact with a portion of the user interface in a specified way.

The foregoing summary is illustrative only and is not intended to be in any way limiting. In addition to the illustrative aspects, embodiments, and features described above, further aspects, embodiments, and features will become apparent by reference to the figures and the following detailed description.

### BRIEF DESCRIPTION OF THE FIGURES

FIG. 1 is a block diagram illustration of a computing device, according to example embodiments.

FIG. 2 is a block diagram illustration of a cloud-based server cluster, according to example embodiments.

FIG. 3A is a block diagram illustration of a computing system, according to example embodiments.

FIG. 3B is an illustration of a computing system, according to example embodiments.

FIG. 3C is an illustration of a computing system, according to example embodiments.

FIG. 4A is a block diagram illustration of a computing system, according to example embodiments.

FIG. 4B is an illustration of a computing system, according to example embodiments.

FIG. 4C is an illustration of a computing system, according to example embodiments.

FIG. 4D is an illustration of a computing system, according to example embodiments.

FIG. 5A is a block diagram illustration of a distributed computing system, according to example embodiments.

FIG. 5B is a block diagram illustration of a distributed computing system, according to example embodiments.

FIG. 6 is a flowchart illustration of a method, according to example embodiments.

### DETAILED DESCRIPTION

Example methods, devices, and systems are described herein. It should be understood that the words “example” and “exemplary” are used herein to mean “serving as an example, instance, or illustration.” Any embodiment or feature described herein as being an “example” or “exemplary” is not necessarily to be construed as preferred or advantageous over other embodiments or features unless stated as such. Thus, other embodiments can be utilized and other changes can be made without departing from the scope of the subject matter presented herein.

Accordingly, the example embodiments described herein are not meant to be limiting. It will be readily understood that the aspects of the present disclosure, as generally described herein, and illustrated in the figures, can be arranged, substituted, combined, separated, and designed in a wide variety of different configurations. For example, the separation of features into “client” and “server” components may occur in a number of ways.

Further, unless context suggests otherwise, the features illustrated in each of the figures may be used in combination with one another. Thus, the figures should be generally viewed as component aspects of one or more overall embodiments, with the understanding that not all illustrated features are necessary for each embodiment.

Additionally, any enumeration of elements, blocks, or steps in this specification or the claims is for purposes of clarity. Thus, such enumeration should not be interpreted to require or imply that these elements, blocks, or steps adhere to a particular arrangement or are carried out in a particular order.

### I. OVERVIEW

Example embodiments relate to systems and methods for utilizing idle computing capacity. As described above, computing devices can be used to perform various tasks. As described herein, such tasks may be performed repetitively. For example, a computing device (e.g., with an associated camera) may repeatedly capture and/or analyze photos of a given physical location in order to monitor that physical location (e.g., monitor safety, weather conditions, traffic congestion, etc.). Such commands may be initiated by one or more inputs (e.g., from a user) at a user interface, for instance. However, it may be overly cumbersome (or, in the extreme, completely intractable) for a user to initiate these tasks on the computing device over a prolonged period of time or across a multitude of different devices simultaneously. Given this, techniques described herein include a controller, such as a single board computing device (“SBCD”), that is configured to provide one or more instructions to another computing device (e.g., a “device under test” or “DUT”) in order to automate repeated tasks. Such instructions may be based on a predefined workflow (e.g., a workflow programmed by a test engineer and stored within a memory associated with the controller and/or within a memory of a server) that is designed to complete a specified task (e.g., a software quality assurance test, a physical location monitoring, a customer service response task, etc.). In some embodiments, the predefined workflow may be coordinated (e.g., by a broker server device) across a plurality of SBCDs and associated DUTs. Such a distribution may allow for different physical locations of the respective DUTs and/or may allow for parallel execution of tasks (e.g., resulting in computational speed up).

An example computing system according to the techniques described herein may be approximately the size of a shoebox (e.g., about 14 in.×8 in.×5 in.), in some embodiments. As such, the computing system may represent a small “phone booth” or container for a mobile phone (e.g., a DUT). Inside the container, there is the mobile phone and a small SBCD (e.g., a RASPBERRY PI) physically coupled to one another on a chassis. The SBCD may be used to execute functions on the mobile phone. In some embodiments, instead of a mobile phone, the DUT may include a tablet computer or any other device with processing capacity, portable or otherwise.

In some embodiments, some sides of the container may be open (i.e., the container might not be fully enclosed and may instead be partially enclosed, if enclosed at all). In some embodiments, sides of the container may include glass, clear plastic, or a similar substance through which a user can observe the inside of the container and/or the DUT.

In order to determine instructions to provide to the DUT, the SBCD may receive feedback regarding what is presently occurring on the DUT (e.g., on a graphical user interface, GUI, of the DUT). For example, the SBCD may be connected to a camera that is configured to capture images or a video stream usable to identify images, text, and other output on the GUI of the DUT (e.g., on a phone's screen). Further, the SBCD may be connected to a universal serial bus (USB) cable (or other communication cable). The other end of the USB cable may be connected to the DUT. Through the USB cable, the SBCD can act as a virtual stylus, mouse, and/or keyboard to send inputs/instructions to the DUT. The DUT's connection to the Internet, audio in/out, video in/out, etc. may also be provided to the DUT from the SBCD via the USB cable. This may isolate the DUT from the outside world. Further, in some embodiments, the DUT and/or the SCBD may be fully enclosed within a faraday cage to attenuate any electromagnetic signals. Such attenuation can prevent external signals from being communicated to or internal signals from being communicated from the DUT (e.g., thereby ensuring that all communications with and network traffic to/from the DUT is mediated by the SBCD). In some embodiments, all or at least some communications (e.g., Internet traffic, mobile data communications, etc.) into or out of the DUT may controlled by the SBCD using the USB cable. In alternate embodiments, the SBCD and the DUT may communicate with one another wirelessly.

Additionally, the DUT and/or the SBCD may be connected to one or more external power supplies (e.g., at one or more power supply ports within the container). For example, the DUT and the SBCD may be connected to one or more power supplies using multiple cables or a single, shared cable. The external power supply may include a USB connection (e.g., a USB Type-C connection) to a wall socket (e.g., via an inverter) or a personal computer, in various embodiments.

As an example use case, a DUT could be accessed or used (e.g., hired) for computing resources at a time when the DUT would otherwise go unused. For example, a DUT (e.g., a mobile phone) may be expected to be idle the vast majority of the time (e.g., when a user of the mobile phone is sleeping). This otherwise idle time may be provided for use (e.g., in return for a fee) for other users' computing tasks. Given the techniques described herein, while one side of the world is working (and, therefore, desiring access to compute capacity) and the other side of the world is asleep (where, presumably, the DUTs would otherwise be 100% idle or at least have some idle compute capacity), compute power can be transferred from sleeping users to working users.

Since the DUTs may be connected to the Internet in a controlled manner (e.g., via the SBCD), this idle processing capacity can be used for various third-party computational tasks. These include, but are not limited to, data analysis, training machine learning models, calculating protein folding characteristics, cryptocurrency mining, software testing, software distribution, and so on. The processors used (e.g., on the DUTs and/or the SBCDs) could be one or more general purpose central processing units (CPUs) or graphical processing units (GPUs), for example.

In some situations, there may be many such connected DUTs, each with a potentially different amount of idle processing capacity. These distributed DUTs may be controlled centrally to allocate their idle processing capacities to one or more users or entities. A centralized (e.g., cloud-based) server may receive indications of when each DUT has idle computing capacity, for how long the DUT is expected to be idle, the DUT's amount of idle compute capacity (e.g., number and types of processors), and a cost or price per unit of compute time (e.g., 1 dollar per hour). Then, the centralized server may act as a broker for distributing various compute jobs to the DUTs. In other embodiments, a related distributed computing system may be performed without using a server acting as a broker. For example, multiple SBCDs may communicate with one another (e.g., over a network, such as the Internet) and/or with a requesting computing device to control the functions of DUTs connected to the SBCDs in order to carry out a joint predefined workflow among the DUTs.

As one example, a user may log on to the centralized server (e.g., via a user interface on a web browser using one or more login credentials) and submit a compute job. A centralized server may then determine a set of one or more available DUTs and a total cost to perform the compute job. The user may then either accept this offer (thus causing the job to be distributed to the DUTs for execution) or reject the offer. Additionally or alternatively, a subscription-based model may be used (e.g., where a user pays a subscription fee for an unlimited amount or predefined amount of compute jobs, compute time, or data communicated within a predefined period, such as a month or a year).

In some cases, the centralized server may present the user with a graphical user interface indicating various sortable options to select a group of DUTs based on their expected speed of performing the compute job, their associated cost for doing so, reputation scores associated with the DUTs, accumulated DUT time on the network, the type of DUT (e.g., APPLE IPHONE or SAMSUNG GALAXY), DUT operating system (e.g., IOS or ANDROID), operating system version, geographic location or region, CPU or GPU type, telecom network or Internet provider, or other statuses, attributes, or properties (e.g., stationary, in motion, etc.).

When a compute job is distributed to a DUT, it may be executed by the DUT on a virtual machine (e.g., a Java Virtual Machine, JVM) or in an otherwise sandboxed environment. This would isolate the execution from underlying processing that otherwise would need to be carried out by the DUT's operating system and other applications. When the DUT completes the compute job, it may return the results to the SBCD and the SBCD may relay the results to the centralized server (e.g., and, thereafter, the centralized server may communicate the results back to the original device making the request).

In some cases, the centralized server may split the compute job into discrete and at least semi-independent subtasks, each distributable to a DUT. This means that a compute job may be split into n subtasks that are then distributed to m DUTs. In some cases, n>m and thus multiple subtasks may be provided to and executed by the same DUT (either serially or in parallel).

In some embodiments, a crowdsourced model may be applied to the SBCDs/DUTs and the control thereof. This would allow owners of the DUTs to lease out the idle computer capacity of their DUTs, and potentially be compensated for this use (e.g., with real-world currency, credits, tokens, cryptocurrency, or some other item of value). As the crowdsourced network grows, both buyers (parties with compute jobs) and suppliers (owners of the DUTs) would earn reputation scores (e.g., as a result of one or more ratings or reviews from other parties with which they previously transacted). Such reputation scores may build trust between users of the service. Additionally or alternatively, advertisements may be displayed to users when submitting compute jobs or supplying DUT computing resources. In some embodiments, revenue (e.g., including advertisement revenue) may be split between the operator of the centralized server (as the network provider and market maker) and the DUT suppliers.

### II. EXAMPLE SYSTEMS

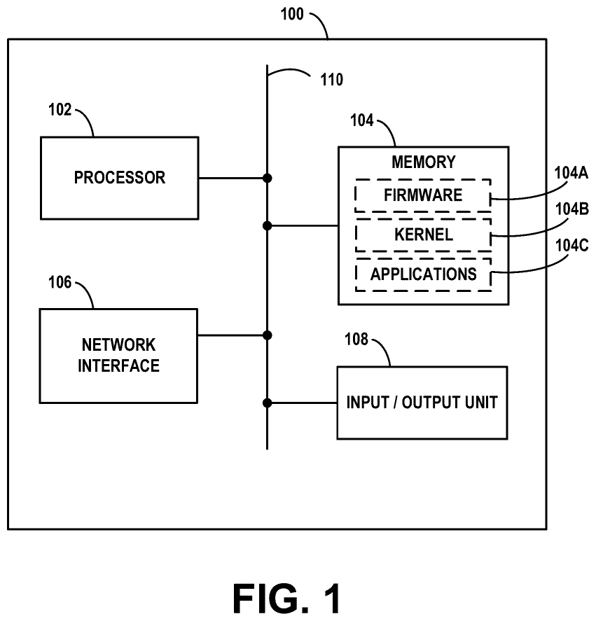

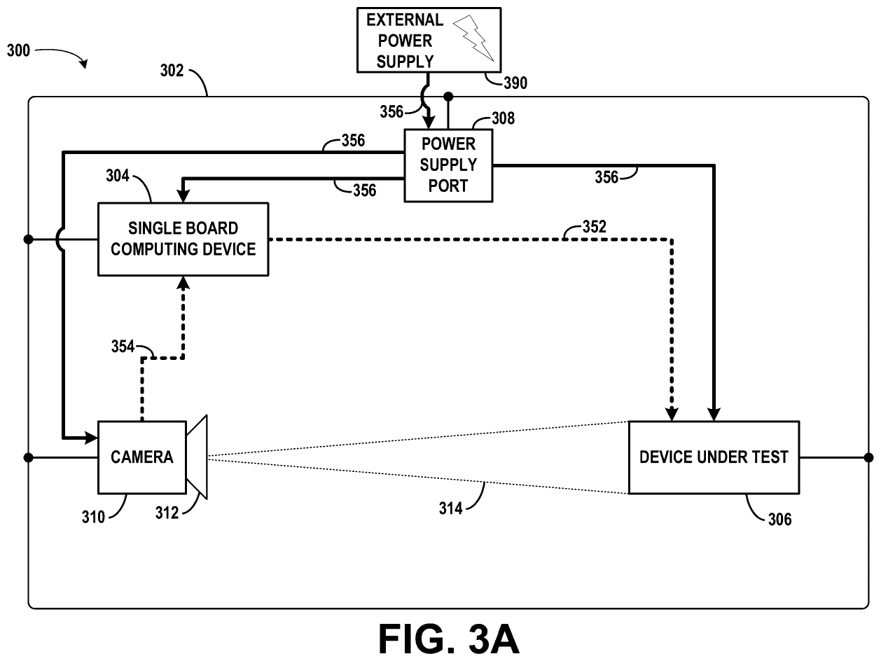

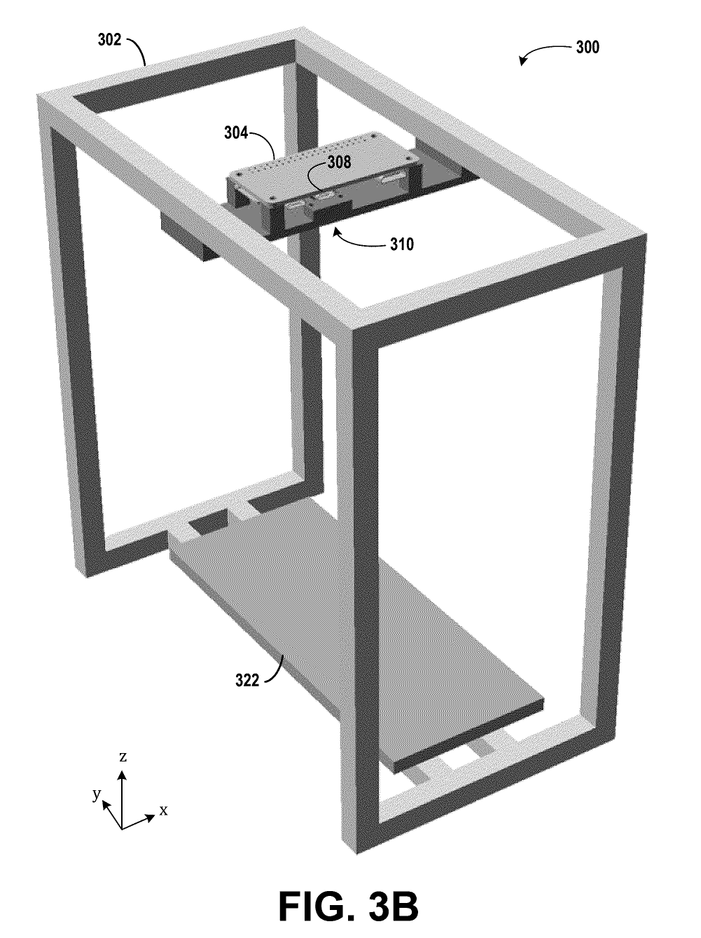

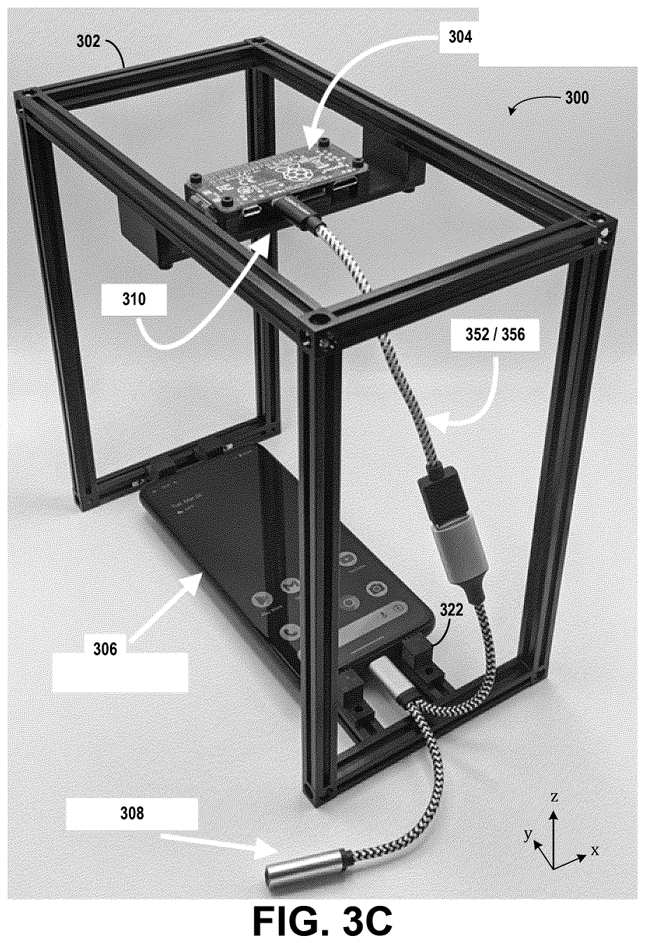

FIG. 1 is a block diagram of a computing device 100, according to example embodiments. FIG. 1 illustrates some of the components that may be included in a computing device arranged to operate in accordance with the embodiments herein. For example, the computing device 100 may represent portions of a SBCD (e.g., the SBCD 304 shown and described below with reference to FIGS. 3A-5B) or of a DUT (e.g., the DUT 306 shown and described below with reference to FIGS. 3A, 4A, 4D, 5A, and 5B). Computing device 100 may be a client device (e.g., a device actively operated by a user), a server device (e.g., a device that provides computational services to client devices), or some other type of computational platform. Some server devices may operate as client devices from time to time in order to perform particular operations, and some client devices may incorporate server features.

In this example, computing device 100 includes processor 102, memory 104, network interface 106, and input/output unit 108, all of which may be coupled by system bus 110 or a similar mechanism. In some embodiments, computing device 100 may include other components and/or peripheral devices (e.g., detachable storage, printers, and so on).

Processor 102 may be one or more of any type of computer processing element, such as a CPU, a co-processor (e.g., a mathematics, graphics, or encryption co-processor), a digital signal processor (DSP), a network processor, and/or a form of integrated circuit or controller that performs processor operations. In some cases, processor 102 may be one or more single-core processors. In other cases, processor 102 may be one or more multi-core processors with multiple independent processing units. Processor 102 may also include register memory for temporarily storing instructions being executed and related data, as well as cache memory for temporarily storing recently-used instructions and data.

Memory 104 may be any form of computer-usable memory, including but not limited to random access memory (RAM), read-only memory (ROM), and non-volatile memory (e.g., flash memory, hard disk drives, solid state drives, compact discs (CDs), digital video discs (DVDs), and/or tape storage). Thus, memory 104 represents both main memory units, as well as long-term storage. Other types of memory may include biological memory.

Memory 104 may store program instructions and/or data on which program instructions may operate. By way of example, memory 104 may store these program instructions on a non-transitory, computer-readable medium, such that the instructions are executable by processor 102 to carry out any of the methods, processes, or operations disclosed in this specification or the accompanying drawings.

As shown in FIG. 1, memory 104 may include firmware 104A, kernel 104B, and/or applications 104C. Firmware 104A may be program code used to boot or otherwise initiate some or all of computing device 100. In some embodiments, for example, firmware 104A may include a basic input/output system (BIOS). Kernel 104B may be an operating system, including modules for memory management, scheduling and management of processes, input/output, and communication. Kernel 104B may also include device drivers that allow the operating system to communicate with the hardware modules (e.g., memory units, networking interfaces, ports, and buses) of computing device 100. Applications 104C may be one or more user-space software programs (e.g., mobile applications), such as web browsers or email clients, as well as any software libraries used by these programs. Memory 104 may also store data used by these and other programs and applications.

Network interface 106 may take the form of one or more wireline interfaces, such as Ethernet (e.g., Fast Ethernet, Gigabit Ethernet, and so on). Network interface 106 may also support communication over one or more non-Ethernet media, such as coaxial cables or power lines, or over wide-area media, such as Synchronous Optical Networking (SONET) or digital subscriber line (DSL) technologies. Network interface 106 may additionally take the form of one or more wireless interfaces, such as IEEE 802.11 (WIFI), BLUETOOTH, global positioning system (GPS), or a wide-area wireless interface. However, other forms of physical layer interfaces and other types of standard or proprietary communication protocols may be used over network interface 106. Furthermore, network interface 106 may comprise multiple physical interfaces. For instance, some embodiments of computing device 100 may include Ethernet, BLUETOOTH, and WIFI interfaces.

Input/output unit 108 may facilitate user and peripheral device interaction with computing device 100. Input/output unit 108 may include one or more types of input devices, such as a keyboard, a mouse, a touch screen, and so on. Similarly, input/output unit 108 may include one or more types of output devices, such as a screen, monitor, printer, and/or one or more light emitting diodes (LEDs). Additionally or alternatively, computing device 100 may communicate with other devices using a USB or high-definition multimedia interface (HDMI) port interface, for example.

In some embodiments, one or more computing devices like computing device 100 may be deployed to support the embodiments herein. The exact physical location, connectivity, and configuration of these computing devices may be unknown and/or unimportant to client devices. Accordingly, the computing devices may be referred to as “cloud-based” devices that may be housed at various remote data center locations.

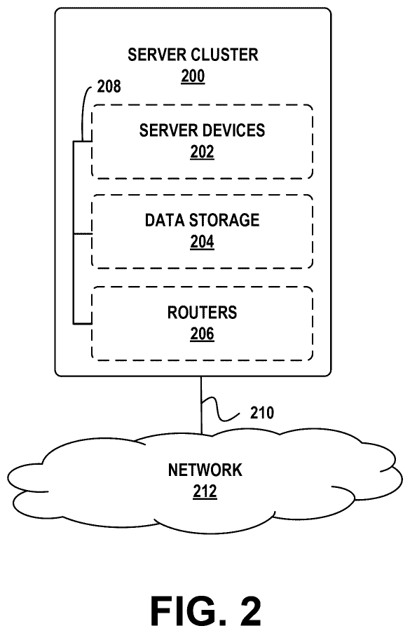

FIG. 2 depicts a server cluster 200 (e.g., a cloud-based server cluster) in accordance with example embodiments. In FIG. 2, operations of a computing device (e.g., computing device 100) may be distributed between server devices 202, data storage 204, and routers 206, all of which may be connected by local cluster network 208. The number of server devices 202, data storages 204, and routers 206 in server cluster 200 may depend on the computing task(s) and/or applications assigned to server cluster 200.

For example, server devices 202 can be configured to perform various computing tasks of computing device 100. Thus, computing tasks can be distributed among one or more of server devices 202. To the extent that these computing tasks can be performed in parallel, such a distribution of tasks may reduce the total time to complete these tasks and return a result. For purposes of simplicity, both server cluster 200 and individual server devices 202 may be referred to as a “server device.” This nomenclature is understood to imply that one or more distinct server devices, data storage devices, and cluster routers may be involved in server device operations.

Data storage 204 may be data storage arrays that include drive array controllers configured to manage read and write access to groups of hard disk drives and/or solid state drives. The drive array controllers, alone or in conjunction with server devices 202, may also be configured to manage backup or redundant copies of the data stored in data storage 204 to protect against drive failures or other types of failures that prevent one or more of server devices 202 from accessing units of data storage 204. Other types of memory aside from drives may be used.

Routers 206 may include networking equipment configured to provide internal and external communications for server cluster 200. For example, routers 206 may include one or more packet-switching and/or routing devices (including switches and/or gateways) configured to provide: (i) network communications between server devices 202 and data storage 204 via local cluster network 208 and/or (ii) network communications between server cluster 200 and other devices via communication link 210 to network 212.

Additionally, the configuration of routers 206 can be based at least in part on the data communication requirements of server devices 202 and data storage 204; the latency and throughput of the local cluster network 208; the latency, throughput, and cost of communication link 210; and/or other factors that may contribute to the cost, speed, fault-tolerance, resiliency, efficiency, and/or other design goals of the system architecture.

As a possible example, data storage 204 may include any form of database, such as a structured query language (SQL) database. Various types of data structures may store the information in such a database, including but not limited to tables, arrays, lists, trees, and tuples. Furthermore, any databases in data storage 204 may be monolithic or distributed across multiple physical devices.

Server devices 202 may be configured to transmit data to and receive data from data storage 204. This transmission and retrieval may take the form of SQL queries or other types of database queries, and the output of such queries, respectively. Additional text, images, video, and/or audio may be included as well. Furthermore, server devices 202 may organize the received data into web page or web application representations (e.g., accessible via a web browser). Such a representation may take the form of a markup language, such as HyperText Markup Language (HTML), extensible Markup Language (XML), or some other standardized or proprietary format. Moreover, server devices 202 may have the capability of executing various types of computerized scripting languages, such as, but not limited to, Perl, Python, PHP Hypertext Preprocessor (PHP), Active Server Pages (ASP), JAVASCRIPT, and so on. Computer program code written in these languages may facilitate the providing of web pages to client devices, as well as client device interaction with the web pages. Alternatively or additionally, JAVA may be used to facilitate generation of web pages and/or to provide web application functionality.

FIG. 3A is an illustration of a computing system 300, according to example embodiments. The computing system 300 may correspond to the container for the DUT described above, for example. As illustrated, the computing system 300 may include a chassis 302, a SBCD 304, a DUT 306, a power supply port 308, a camera 310, one or more power couplings 356, and one or more communication channels 352, 354. Further, the computing system 300 may be coupled to an external power supply 390 (e.g., where the external power supply 390 is not a component of the computing system 300) at the power supply port 308.

The chassis 302 may be an arrangement of physical components used to house or hold one or more of the other components. For example, the chassis 302 may represent an enclosure or a container in which, on which, or to which the other components are attached. As illustrated in FIG. 3A by the lines terminating in dots along the chassis 302, at least the SBCD 304, the DUT 306, the power supply unit 308, and the camera 310 may be physically coupled to the chassis 302 (e.g., permanently attached to the chassis 302 or removably attached to the chassis 302).

Notably, the physical arrangement of components in FIG. 3A is for purposes of illustration. Thus, they may not be to scale nor do they necessarily correspond to an exact representation of the physical relationships (e.g., positioning and spacings) between these components.

In some embodiments, the chassis 302 may include some combination of aluminum extrusion, nuts, bolts, three-dimensionally (3D) printed components (e.g., printed from polylactic acid, PLA), and/or laser-cut acrylic. Additionally or alternatively, the chassis 302 may include magnets, hinges, washers, brackets, screws, nails, or cushions. Cushions may include, for example, pieces (e.g., cylindrical pieces) that are configured to assist in stabilizing a device (e.g., the SBCD 304 or the DUT 306) and are made at least partially out of a soft material (e.g., foam or rubber). In some embodiments, the chassis 302 may be fabricated to include one or more camera holders, SBCD holders, DUT holders, power supply port holders, etc. For example, the chassis 302 may include a platform on which the DUT 306 may be positioned (e.g., and secured using one or more bolts, brackets, and/or cushions). An example DUT platform 322 is pictured in the illustration of the computing system 300 in FIG. 3B. The chassis 302 may take a variety of shapes and sizes in various embodiments. As just one example (e.g., as illustrated in FIGS. 3B and 3C), the chassis 302 may include a frame of aluminum or steel formed into the shape of a rectangular prism and having dimensions of about 23 cm (width)×13 cm (depth)×24 cm (height) or, in other embodiments, about 24 cm (width)×12 cm (depth)×8.7 cm (height). The latter dimensions may correspond to a total weight of about 600 grams.

The SBCD 304 may determine instructions to be executed by the DUT 306 and provide those instructions (e.g., sequentially) to the DUT 306 (e.g., over the communication channel 352). As described above, the SBCD 304 may include one or more components of the computing device 100 shown and described with reference to FIG. 1. In some embodiments, the instructions determined by the SBCD 304 for the DUT 306 may be determined by the SBCD 304 based on input indicative of content currently being displayed on a user interface (e.g., a display/screen) of the DUT 306. Such input may be received from the camera 310 (e.g., over communication channel 354). While the SBCD 304 is described herein as a computing device that includes a “single board,” it is understood that multiple printed circuit boards and/or other modules may be used in various embodiments of the SBCD 304. For example, in some embodiments, the SBCD 304 may, itself, be a mobile computing device or a tablet computing device.

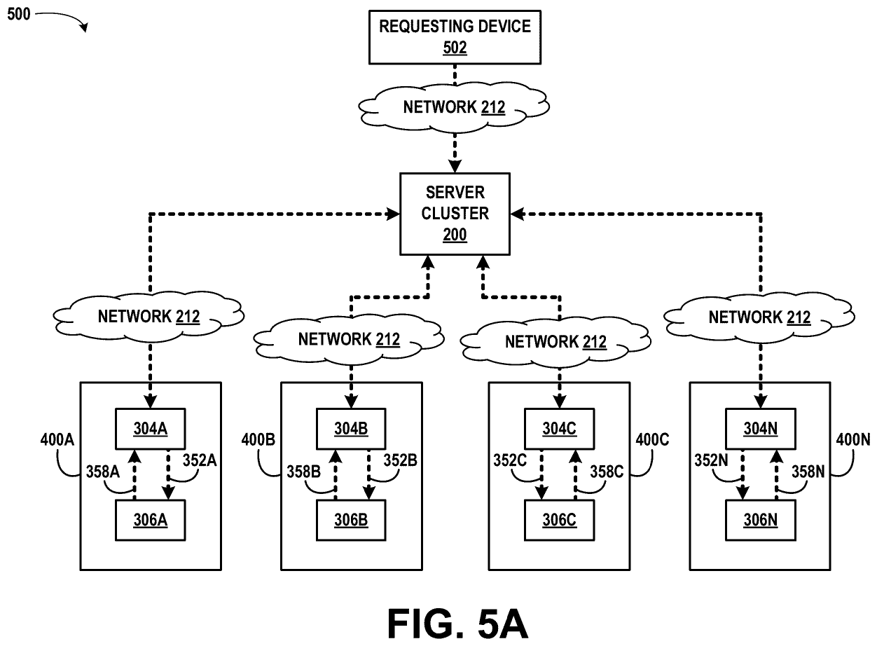

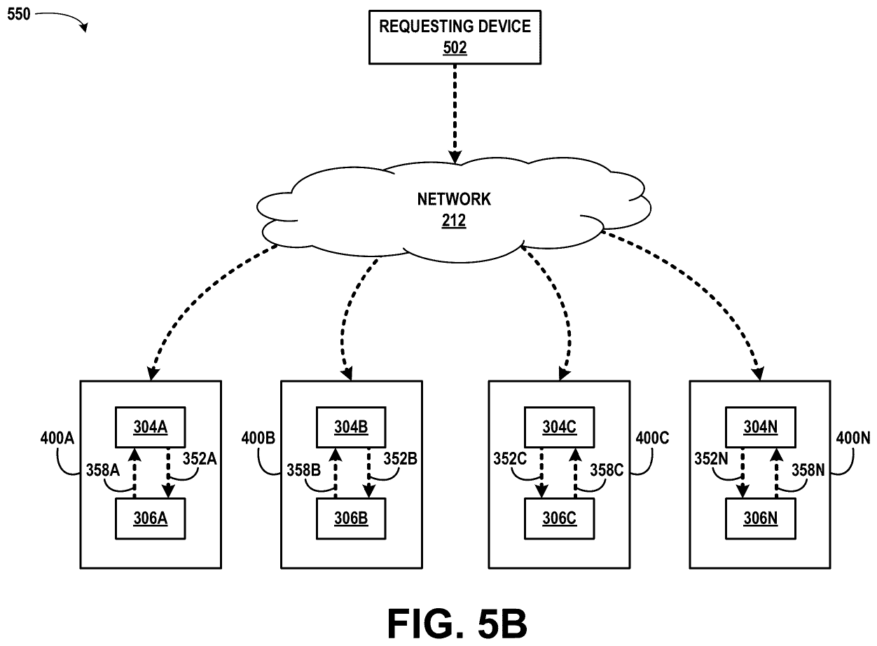

The SBCD 304 may determine instructions to provide to the DUT 306 based on a predefined workflow. The predefined workflow may be stored within the memory 104 of the SBCD 304 and/or transmitted to the SBCD 304 (e.g., from a server cluster 200). Further, in some embodiments, the predefined workflow may be based on one or more computing jobs (e.g., submitted by a user to the server cluster 200) requested to be performed by one or more DUTs. In some embodiments, the results of processes performed by the DUT 306 (e.g., and communicated to the SBCD 304 based on one or more images captured by the camera 310) may be communicated back to a server cluster 200 (e.g., and, thereafter, back to a computing device that initially submitted the associated job request). As such, though not illustrated in FIG. 3A, it is understood that the SBCD 304 may include one or more network interfaces 106 configured to provide communication between the SBCD 304 and a server cluster 200 (e.g., as shown and described with reference to FIG. 5A) and/or between the SBCD 304 and other SBCDs coordinating with other DUTs (e.g., as shown and described with reference to FIG. 5B). For example, the SBCD 304 may include a wireless connection or a wireline connection to the Internet. As such, the SBCD 304 may be configured to receive at least a portion of the predefined workflow from an authorized user device (e.g., authorized by a server cluster 200) via the Internet.

The SBCD 304 may determine instructions for the DUT 306 by, in some embodiments, by executing instructions written in Python, HyperText Transfer Protocol (HTTP) or JavaScript Object Notation (JSON) that are stored in a memory 104 of and/or transmitted to the SBCD 304. Further, in order to facilitate communication (e.g., between the SBCD 304 and a server cluster 200, between the SBCD 304 and another SBCD, and/or between the SBCD 304 and a third-party user device), the SBCD 304 may be configured to trigger instructions in response to one or more requests received by an Application Programming Interface (API). The API may also be used to instruct the SBCD 304 to provide response information (e.g., screenshots or a video feed of the DUT 306) over a network (e.g., the Internet) back to the requester. Further, a memory 104 of the SBCD 304 may have one or more libraries stored thereon to enhance the capabilities of the SBCD 304. For example, the OpenCV library may be stored within a memory 104 of the SBCD 304 to improve image manipulation and analysis of images of the DUT 306 captured by the camera 310. Additionally or alternatively, a memory 104 of the SBCD 304 may include one or more object-identification, machine-learning libraries (e.g., classifiers) that are usable to identify objects (e.g., icons, mobile apps, messages, text, etc.) within one or more images of the DUT 306 captured by the camera 310 and transmitted to the SBCD 304.

In various embodiments, the SBCD 304 may take a variety of form factors. As just one example, the SBCD 304 may include a single printed circuit board (PCB) with a variety of computing components (e.g., the components shown and described with reference to FIG. 1) located and interconnected thereon. For example, the SBCD 304 may include a RASPBERRY PI 4 Model B. As such, a processor 102 of the SBCD 304 may include a BROADCOM BCM2711, which is a quad-core cortex-A72 (ARM v8) 64-bit System on a Chip (SoC) processor that has a clock speed of 1.8 GHz. Other processor architectures are also possible and are contemplated herein. Additionally, the memory 104 of the SBCD 304 may include an 8 GB Low-Power Double Data Rate 4 (LPDDR4)-3200 Synchronous Dynamic Random Access Memory (SDRAM). Other memories are also possible and are contemplated herein. Further, the memory 104 may include a 64 GB Micro-Secure Digital (MicroSD) card. The MicroSD card may have a kernel 104B (e.g., including the RASPBERRY PI Operating System (OS), such as a 64-bit version of the RASPBERRY PI OS that has been optimized to enhance interaction efficiency between the SBCD 304 and the DUT 306) and a predefined workflow for determining instructions for the DUT 306 stored thereon.

In addition, the SBCD 304 may include (e.g., as part of the network interface 106) a Gigabit Ethernet interface and a dual-band 802.11ac wireless Local Area Network (LAN) WIFI interface. As such, the SBCD 304 may be configured to interface with (e.g., take instructions from and provide feedback to) one or more other computing devices over a network. For example, the SBCD 304 may be capable of interfacing with another computing device (e.g., a server device) that is running MAC OS, WINDOWS OS, or LINUX OS. Further, the SBCD 304 may include (e.g., as part of the input/output unit 108) a BLUETOOTH 5.0 interface, one or more USB 3.0 ports, one or more USB 2.0 ports, one or more HDMI ports (e.g., micro HDMI ports configured to support up to 4K resolution at 60 frames per second), and one or more 3.5 mm analog audio-video jack. In some embodiments, in order to properly interface with the DUT 306 and/or the camera 310, one or more converters may be used. For example, the SBCD 304 may include a bridge device (e.g., the TOSHIBA TC358743XBG) that converts from an HDMI stream to a Mobile Industry Processor Interface (MIPI) Camera Serial Interface 2 (CSI-2).

The DUT 306 may take the form of various computing devices in various embodiments. For example, the DUT 306 may include a mobile computing device (e.g., mobile phone) or a tablet computing device. In some embodiments, the DUT 306 may have certain connections disabled. For example, WIFI connections, wireless data connections (e.g., through a mobile carrier), and/or BLUETOOTH connections may be disabled. In this way, the DUT 306 may only communicate with (e.g., receive instructions from and/or provide feedback to) the SBCD 304 (e.g., via the communication channel 352). By disabling one or more connections, receipt of conflicting instructions from disparate sources may be avoided and/or additional computational resources (e.g., processor cores, RAM space, etc.) may be freed up.

As illustrated in FIG. 3A, the SBCD 304 may provide information to the DUT 306 over the communication channel 352 (e.g., a wired communication channel, such as one or more USB cables). The information provided by the SBCD 304 may include instructions usable by the DUT 306 to interact with a portion of the user interface in a specified way. For example, the instructions may be usable by the DUT 306 to perform a screen touch, a swipe gesture, a keystroke, a button press, etc. Further, the instructions from the SBCD 304, when acted on by the DUT 306, may cause an application on the DUT 306 to be installed, to launch, to quit, or to be moved the background of the user interface of the DUT 306. Additionally or alternatively, the instructions from the SBCD 304, when acted on by the DUT 306, may address or delete a notification displayed on the user interface of the DUT 306. Still further, the instruction from the SBCD 304, when acted on by the DUT 306, may result in data being extracted from an application of the DUT 306, data being entered into an application of the DUT 306, a message being composed on the DUT 306, a message being read on the DUT 306, a message on the DUT 306 being deleted, an email being composed on the DUT 306, an email on the DUT 306 being read, an email on the DUT 306 being deleted, a BLUETOOTH connection being enabled on the DUT 306, a BLUETOOTH connection being disabled on the DUT 306, a WIFI connection being enabled on the DUT 306, a WIFI connection being disabled on the DUT 306, mobile data usage being enabled on the DUT 306, mobile data usage being disabled on the DUT 306, or backing up data in the DUT 306 into an external storage or cloud storage.

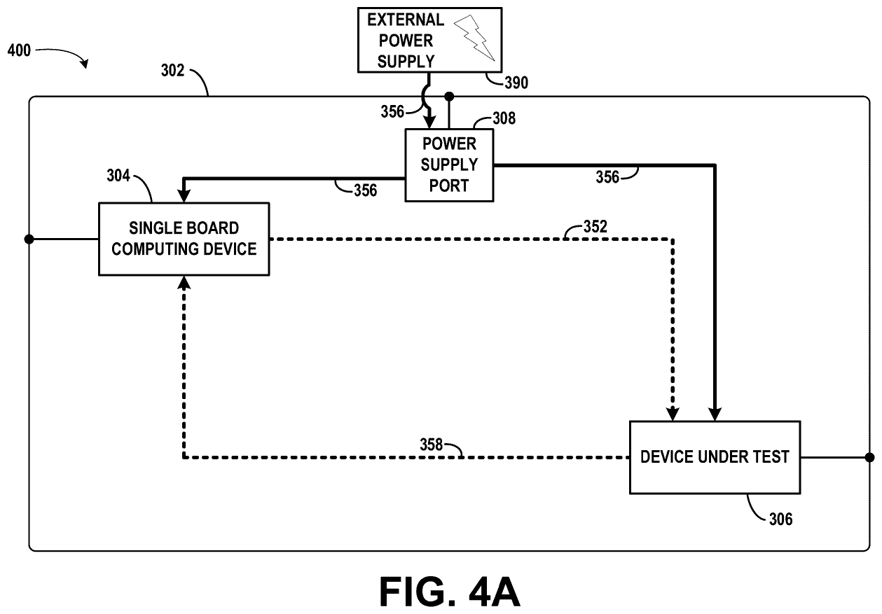

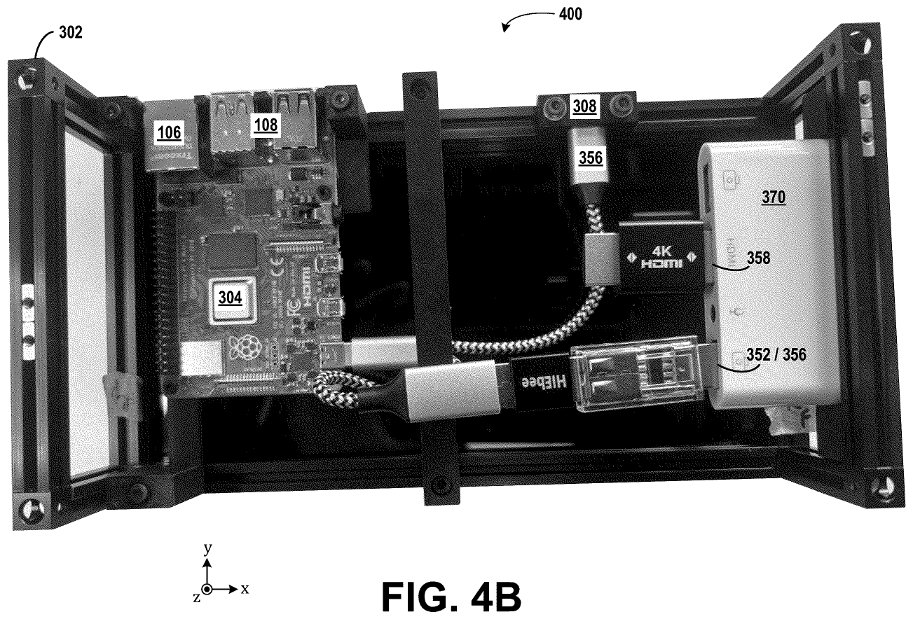

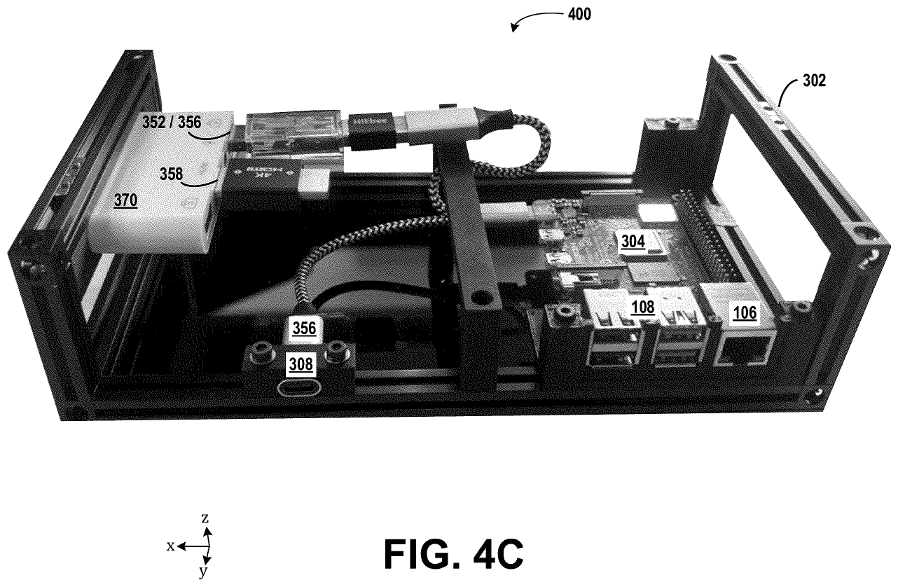

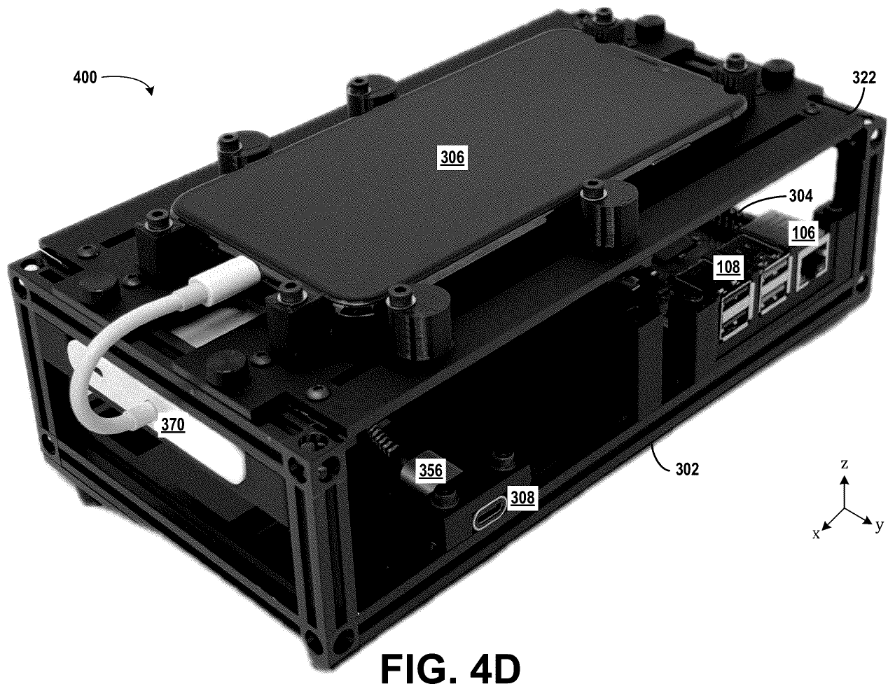

As just one example, the DUT 306 may be an IPHONE generation 7 or later. As such, the DUT 306 may be running IOS generation 13 or later, for example. In such embodiments, the communication channel 352 may include a LIGHTNING adapter connected to a port of the DUT 306. In this way, the DUT 306 may receive one or more instructions, determined by the SBCD 304, over the LIGHTNING adapter. Additionally or alternatively, in some embodiments (e.g., as shown and described below with reference to FIGS. 4A-4D), the DUT 306 may provide information indicative of content being displayed on a user interface of the DUT 306 back to the SBCD 304 (e.g., in addition to or instead of the camera 310 capturing images of the DUT 306 and providing those images to the SBCD 304 to indicate content being displayed on a user interface of the DUT 306). In such embodiments, the LIGHTNING adapter may also be used by the DUT 306 to communicate the information indicative of content being displayed on a user interface of the DUT 306 to the SBCD 304. In some embodiments, a USB-C cable or other power and/or data cable may be used in addition to or instead of the LIGHTNING adapter. Further, while an IPHONE with a LIGHTNING adapter is described above, it is understood that, throughout this disclosure, other types of mobile devices are also possible and are contemplated herein. For example, an ANDROID device (e.g., a SAMSUNG GALAXY or a GOOGLE PIXEL) could be used in place of an IPHONE. Other devices (e.g., other devices controllable by USB human interface devices (HIDs), such as mice, keyboards, or touch pads) are also possible.

The power supply port 308 may include a port that is connectable to a power supply that is external to the computing system 300. For example, as illustrated, an external power supply 390 may be connectable to the power supply port 308 over a power coupling 356 (e.g., a cable, such as a USB cable). Further, in such embodiments, the power supply port 308 may include a USB port (e.g., USB Type-C port), for instance.

As also illustrated in FIG. 3A, the power supply port 308 may be physically coupled to (e.g., attached to) the chassis 302. As just one example, the external power supply 390 may include a wall socket with an associated alternating current to direct current (AC to DC) inverter. For instance, the external power supply 390 may convert a 27 W, 100 V-240 V AC, 50 Hz and/or 60 Hz input into a 5.1 V and 5 A DC output. In some embodiments, for example, the external power supply 390 may include a power supply associated with the SBCD 304 (e.g., associated with a RASPBERRY PI). The power supply port 308 may be coupled to one or more other components of the computing system 300 to supply power to one or more other components of the computing system 300. For example, as illustrated, the SBCD 304, the DUT 306, and the camera 310 may be configured to receive electrical power from the power supply port 308 via a plurality of power couplings 356 (e.g., USB cables). In some embodiments, however, the power supply port 308 may only be directly connected to a single component (e.g., solely the SBCD 304) and then that single component may, in turn, provide power to all the other components of the computing system 300 (e.g., the SBCD 304 may provide power to the camera 310 and/or the DUT 306 thereafter). For example, in some embodiments, there may be one or more electrical relays between components of the computing system 300. Such electrical relays may allow for the programmatic control of power to one or more components of the computing system 300 and/or the programmatic control of data transfer between two or more components of the computing system 300. In still other embodiments, two or more components of the computing system 300 may have their own respective power supplies/power supply ports.

The camera 310 may include a camera (e.g., a digital camera) configured to capture (e.g., and store) an image and/or a series of images (e.g., a video stream) of an output of the DUT 306 and provide feedback (e.g., the captured data, such as a captured image or captured series of images, indicative of content being displayed on the user interface of the DUT 306) to the SBCD 304 for analysis (e.g., over a communication channel 354, such as a USB cable). For example, the camera 310 may capture what is presently being displayed on a user interface (e.g., a display) of the DUT 306. In some embodiments, the camera 310 may be designed to readily interface with the SBCD 304. For example, the camera 310 may include a RASPBERRY PI camera module v3 (e.g., with a 12 MP image sensor and/or autofocus capabilities). Still further, in some embodiments, the camera 310 may be actuated in order to change zoom, focus, orientation, position, etc.

As illustrated, the camera 310 may be physically coupled to (e.g., attached to) the chassis 302. Further, the camera 310 may include a lens 312 (e.g., a lens corresponding to a 30° field of view 314, a 45° field of view 314, a 60° field of view 314, etc.). The field of view 314 of the lens 312 combined with: the orientation of the camera 310; the position of the camera on the chassis 302 relative to the position and orientation of the DUT 306; and the size and shape of the DUT 306 may allow the camera 310 to capture images of the DUT 306 that span an entire user interface (e.g., the entire display of the DUT 306 may be captured in a single image). In other embodiments, only one or more regions of interest on a user interface of the DUT 306 may be analyzed by the SBCD 304. As such, the position and orientation of the camera 310 and the qualities of the lens 312 may be selected to capture only the one or more regions of interest on the user interface of the DUT 306 (e.g., to capture only the one or more regions of interest at an optimized resolution). In some embodiments, the camera 310 may also include a microphone configured to capture sounds output by the DUT 306 (e.g., at a 3.5 mm jack and/or by a speaker).

FIG. 3B is an illustration (e.g., an isometric view) of a physical arrangement of some of the components of a computing system (e.g., the computing system 300 shown and described above with reference to FIG. 3A). As illustrated, the computing system 300 may include the chassis 302, the SBCD 304, the power supply port 308, and the camera 310. It is understood that the camera 310 (e.g., and associated lens 312) is facing downward in the illustration and is located below the SBCD 304 (and, therefore, is obscured from direct view). Further, the DUT 306 shown and described with reference to FIG. 3A is not illustrated. However, a platform 322 (i.e., DUT 306 support structure) is shown in FIG. 3B (e.g., located below the camera 310 and within a field of view of the camera 310). The DUT 306 may be positioned on the platform 322 (e.g., temporarily secured into place using one or more cushions, bolts, screws, etc.). Further, upon the DUT 306 being positioned on the platform 322, the DUT 306 may be connected to the SBCD 304 using a communication channel (e.g., which includes a USB cable between the SBCD 304 and the DUT 306). In this way, the SBCD 304 can provide instructions to the DUT 306 (e.g., instructions that are usable by the DUT 306 to interact with a portion of the user interface of the DUT 306 in a specified way). As illustrated, one or more sides of the computing system 300 may be at least partially open (i.e., the chassis 302 may not be a complete enclosure of all other components). As such, one or more of the internal components of the computing system 300 (e.g., the SBCD 304, the DUT 306, the camera 310, etc.) may readily be adjusted or swapped out by a technician and/or interconnections between components may be made or changed by a technician (e.g., a USB cable can be connected at one end to the SBCD 304 and at the other end to the DUT 306).

FIG. 3C is an illustration (e.g., an isometric view) of the physical arrangement of some of the components of a computing system (e.g., the computing system shown and described above with reference to FIG. 3A). FIG. 3C is similar to FIG. 3B. However, unlike the illustration of FIG. 3B, in FIG. 3C, the DUT 306 has been placed on the platform 322 of the chassis 302 (e.g., and secured in place using one or more cushions). Further, also unlike the illustration of FIG. 3B, the communication channel 352 and the power coupling 356 have been connected. As illustrated, the communication channel 352 in FIG. 3B and the power coupling 356 in FIG. 3B may be one and the same (e.g., a single USB cable may provide communication between the SBCD 304 and the DUT 306 and may also supply power to both the SBCD 304 and the DUT 306). As also illustrated, the hybrid communication channel 352/power coupling 356 may be attached to the power supply port 308. While the power supply port 308 may allow electrical power to be received (e.g., from an external power supply), similar to FIG. 3A, the power supply port 308 may not be directly physically coupled to the chassis 302 (e.g., unlike in FIG. 3A). Both arrangements of the power supply port 308 are equally possible and are contemplated by the embodiments described herein. Further, it is also understood that the entirety of FIG. 3C is provided solely as an example and that other embodiments and arrangements of the components of the computing system 300 are also possible and are contemplated herein.

FIG. 4A is an illustration of a computing system 400, according to example embodiments. Like the computing system 300 shown and described with reference to FIGS. 3A-3C, the computing system 400 may include a chassis 302, a SBCD 304, a DUT 306, and a power supply port 308 (e.g., which can be coupled to an external power supply 390). Other aspects of the computing system 400 may be similar to aspects of the computing system 300 shown and described with reference to FIG. 3A, as well. However, unlike the computing system 300 of FIGS. 3A-3C, the computing system 400 illustrated in FIG. 4A does not include a camera (and, therefore, does not include a physical coupling between a camera and the chassis 302). Instead, as illustrated, the computing system 400 may include another communication channel 358 (e.g., a wired communication channel, such as a HDMI cable or a USB cable coupled to an output of the DUT 306) between the SBCD 304 and the DUT 306 (e.g., in addition to the communication channel 352). As shown, the communication channel 358 may allow the DUT 306 to directly provide feedback to the SBCD 304 that is indicative of content being displayed on the user interface of the DUT 306 (e.g., rather than using a camera 310 to capture an image of the user interface of the DUT 306 and then provide that image to the SBCD 304 for analysis). As illustrated, the communication channel 352 carrying information from the SBCD 304 to the DUT 306 and the communication channel 358 carrying information from the DUT 306 to the SBCD 304 may be distinct. For example, the communication channel 352 may include a USB cable and the communication channel 358 may include a HDMI cable. In other embodiments, though, the communication channel 352 and the communication channel 358 may be combined into a single, bidirectional communication channel. For example, a single USB cable may be used by the DUT 306 to communicate information to the SBCD 304 and used by SBCD 304 to communicate information to the DUT 306. Additionally or alternatively, in some embodiments, the communication channel 352 and/or the communication channel 358 may be combined with one or more power couplings 356 to simultaneously be used for providing electrical power and for communicating information. For example, in some embodiments, the external power supply 390 may provide electrical power to the power supply port 308, which, in turn, then provides power to the SBCD 304 via a power coupling 356. In tandem, the SBCD 304 may provide both power to and a communication channel (e.g., a bidirectional communication channel) with the DUT 306 using a single cable (e.g., a single USB cable). Further, while wired communication channels are described throughout this disclosure, it is understood that wireless communication channels (e.g., BLUETOOTH, WIFI, etc.) are also possible and are contemplated herein.

FIG. 4B is an illustration (e.g., a top-down view) of a physical arrangement of the computing system 400 shown and described above with reference to FIG. 4A. Relatedly, FIG. 4C is another illustration (e.g., an isometric view) of the physical arrangement of the computing system 400 shown and described above with reference to FIG. 4A. For illustration purposes, it is understood that the DUT 306 and the associated coupling to the chassis 302 (both located above the components illustrated in FIG. 4B) have been removed from the arrangements of FIGS. 4B and 4C to prevent occlusion of other components in the computing system 400 within FIGS. 4B and 4C. As illustrated in FIGS. 4B and 4C, the SBCD 304 (e.g., a RASPBERRY PI) and the power supply port 308 are physically coupled to the chassis 302. The power supply port 308 may include a USB Type-C port, for example. Further, as illustrated, the power coupling 356 (e.g., USB cable) may connect the power supply port 308 to the SBCD 304 and/or the DUT 306 (e.g., to provide electrical power to the SBCD 304 and/or the DUT 306). Further, at least part of the network interface 106 (e.g., an Ethernet port) and the input/output unit 108 (e.g., four USB ports), while not illustrated in FIGS. 3A-3C, are illustrated in FIGS. 4B and 4C (e.g., being defined on and integral with the SBCD 304). Also illustrated in FIGS. 4B and 4C is a connector hub 370. The connector hub 370 may be used to multiplex multiple different parts of the computing system 400 onto a single input/output of the DUT 306 (e.g., a single LIGHTNING port of an IPHONE). For example, as illustrated, a communication channel 358 (e.g., HDMI output) used to provide feedback to the SBCD 304 from the DUT 306 and a hybrid communication channel 352 (used to provide instructions to the DUT 306 from the SBCD 304)/power coupling 356 (used to supply power to the DUT 306) in the form of a USB cable may be multiplexed to the DUT 306 at the connector hub 370. Other types of interconnections are also possible and are contemplated herein (e.g., connections used to ensure compatibility between inputs/outputs of the DUT 306 and inputs/outputs of the SBCD 304 and/or of the power supply port 308).

FIG. 4D is an illustration (e.g., isometric view) of a physical arrangement of the computing system 400 shown and described with reference to FIG. 4A. Unlike FIGS. 4B and 4C, though, the illustration of FIG. 4D includes the platform 322 on which the DUT 306 rests, as well as the DUT 306. As illustrated, the DUT 306 may be secured on the platform 322 using eight cushions (e.g., two cylindrical rests on each side of the DUT 306). Other numbers, types, and positions of cushions are also possible and are contemplated herein. The components illustrated in FIGS. 4B and 4C that are not visible in FIG. 4D are disposed below (e.g., at a location with a smaller z-value) the DUT 306 and the platform 322 (and are therefore occluded by the angle of FIG. 4D). FIG. 4D also shows the connector hub 370 (e.g., connected to the DUT 306 using a LIGHTNING cable), the power supply port 308 and associated power coupling 356, the chassis 302, and the SBCD 304 (including the network interface 106 and the input/output unit 108).

FIG. 5A is a block diagram illustration of a distributed computing system 500, according to example embodiments. As illustrated, the distributed computing system 500 may include a requesting device 502 and a plurality of computing systems 400A, 400B, 400C, 400N (e.g., where each computing system is similar to the computing system 400 shown and described with reference to FIG. 4A or to the computing system 300 shown and described with reference to FIG. 3A). It is understood that, while four computing systems 400A, 400B, 400C, 400N are shown in FIG. 5A, other numbers of computing systems (e.g., one computing system, two computing systems, three computing systems, five computing systems, six computing systems, etc.) are also possible and are contemplated herein. The requesting device 502 and each of the computing systems 400A, 400B, 400C, 400N may be connected to a server cluster (e.g., the server cluster 200 shown and described with reference to FIG. 2) acting as a broker via a network (e.g., the network 212 shown and described with reference to FIG. 2). While multiple instances of the network 212 are illustrated in FIG. 5A, it is understood that each of these networks 212 may be the same network as one another (e.g., the Internet), some of the networks 212 may be the same network as one another, or all networks 212 could be different from one another.

The requesting device 502 may include a client device (e.g., a tablet computing device, a mobile computing device, a personal computer, etc.) configured to request a task be performed by the computing systems 400A, 400B, 400C, 400N. The request may be transmitted to a distributed computing platform (e.g., based on a crowdsourcing model) provided by the server cluster 200, for example. Thereafter, the server cluster 200 may assign tasks to each of the computing systems 400A, 400B, 400C, 400N to be performed (e.g., sequentially or in parallel). For example, the server cluster 200 may communicate with the SBCD 304A, 304B, 304C, 304N of each computing system 400A, 400B, 400C, 400N. The SBCD 304A, 304B, 304C, 304N of each computing system 400A, 400B, 400C, 400N may then cause the DUT 306A, 306B, 306C, 306N of each computing system 400A, 400B, 400C, 400N to perform one or more calculations or execute one or more processes according to the task assigned by the server cluster 200. Next, the respective DUT 306A, 306B, 306C, 306N may return any results from the assigned task to the respective SBCD 304A, 304B, 304C, 304N of each computing system 400A, 400B, 400C, 400N, and these results may then be transmitted to the server cluster 200. Lastly, the server cluster 200 may combine the results received from each of the computing system 400A, 400B, 400C, 400N into a final result and the provide the final result to the requesting device 502.

In some embodiments, in order to transmit a computation request to the distributed computing platform, the requesting device 502 may provide login credentials to the server cluster 200, provide one or more execution options associated with the computation request (e.g., which computing system(s) 400A, 400B, 400C, 400N and/or how many computing system(s) 400A, 400B, 400C, 400N are to be used for the computation request), and/or provide one or more payment details (e.g., to submit one or more real-world currencies, cryptocurrencies, tokens, credits, etc. used to pay for execution of the computation request).

FIG. 5B is a block diagram illustration of a distributed computing system 550, according to example embodiments. The distributed computing system 550 may be similar to the distributed computing system 500. However, unlike the distributed computing system 500 of FIG. 5A, the distributed computing system 550 of FIG. 5B does not include a server cluster 200 as an intermediary between the requesting device 502 and the computing systems 400A, 400B, 400C, 400N. Instead, in the distributed computing system 550 of FIG. 5B, the requesting device 502 may transact directly with the computing systems 400A, 400B, 400C, 400N over the network 212 (e.g., the Internet). This may include the requesting device 502 determining a plurality of tasks (e.g., using a crowdsource app) to divide between and provide to the SBCDs 304A, 304B, 304C, 304N of the computing systems 400A, 400B, 400C, 400N for execution. In the distributed computing system 550 of FIG. 5B, the requesting device 502 may interact with the computing systems' SBCDs 304A, 304B, 304C, 304N of the computing systems 400A, 400B, 400C, 400N using a distributed computing platform (e.g., in order to provide the requests to the SBCDs 304A, 304B, 304C, 304N of the computing systems 400A, 400B, 400C, 400N, in order to receive feedback from the SBCDs 304A, 304B, 304C, 304N of the computing systems 400A, 400B, 400C, 400N, in order to ensure privacy is maintained with the SBCDs 304A, 304B, 304C, 304N of the computing systems 400A, 400B, 400C, 400N, and/or in order to render payment to the SBCDs 304A, 304B, 304C, 304N of the computing systems 400A, 400B, 400C, 400N in return for the computation).

### III. EXAMPLE METHODS

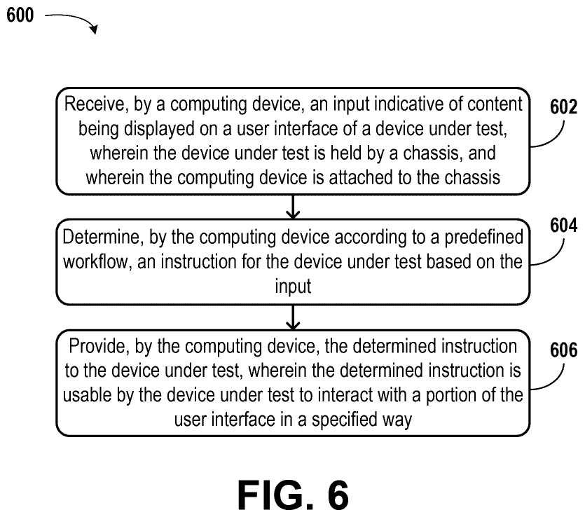

FIG. 6 is a flowchart diagram of a method 600, according to example embodiments. In some embodiments, the method 600 may be performed by a computing system (e.g., the computing system 300 shown and described with reference to FIGS. 3A-3C or the computing system 400 shown and described with reference to FIGS. 4A-4D). Additionally or alternatively, the method 600 may be performed by multiple computing systems (e.g., sequentially or in parallel) as part of a distributed computing system (e.g., the distributed computing system 500 shown and described with reference to FIG. 5A or the computing system 550 shown and described with reference to FIG. 5B).

At block 602, the method 600 may include receiving, by a computing device (e.g., the computing device 304 shown and described with reference to FIGS. 3A-5B), an input indicative of content being displayed on a user interface of a device under test (e.g., the DUT 306 shown and described with reference to FIGS. 3A-5B). The device under test may be held by a chassis (e.g., the chassis 302 shown and described with reference to FIGS. 3A-4D). Further, the computing device may be attached to the chassis.

At block 604, the method 600 may include determining, by the computing device according to a predefined workflow, an instruction for the device under test based on the input.

At block 606, the method 600 may include providing, by the computing device, the determined instruction to the device under test. The determined instruction may be usable by the device under test to interact with a portion of the user interface in a specified way.

In some embodiments of the method 600, the device under test may include a mobile computing device or a tablet computing device.

In some embodiments of the method 600, the predefined workflow may include one or more actions defined within a distributed computing system.

In some embodiments of the method 600, block 606 may include transmitting the determined instruction to the device under test over a wired communication channel. For example, block 606 may include transmitting the determined instruction to the device under test over one or more USB cables.

In some embodiments of the method 600, block 602 may include receiving the image of the user interface of the device under test from a camera configured to capture an image of the user interface of the device under test. For example, block 602 may include receiving the image of the user interface of the device under test from a camera attached to the chassis.

In some embodiments of the method 600, block 602 may include receiving the input over a wired communication channel. For example, block 602 may include receiving the input over an HDMI cable coupled to an output of the device under test.

In some embodiments of the method 600, a power supply port may be coupled to the computing device and attached to the chassis and the method 600 may also include the computing device receiving electrical power from the power supply port when a power supply is connected to the power supply port. The power supply port may include a USB port, for example. Additionally or alternatively, the power supply port may be coupled to the device under test and the method may also include the device under test receiving electrical power from the power supply port when a power supply is connected to the power supply port.

In some embodiments of the method 600, the device under test may include an IPHONE and a LIGHTNING adapter may be connected to a port of the IPHONE. In some embodiments, block 602 may include receiving the input indicative of content being displayed on a user interface of the device under test from the device under test via the LIGHTNING adapter. Additionally or alternatively, block 606 may include providing the determined instruction to the device under test via the LIGHTNING adapter.

In some embodiments of the method 600, the determined instruction provided in block 606 may be usable to perform a screen touch, a swipe gesture, a keystroke, or a button press. For example, the determined instruction may be usable to simulate a button press on a physical button of the device under test. Such a button press may correspond to one or more of the following functionalities: volume up, volume down, mute, power on, power off, restart, confirming app store purchases, taking one or more screenshots, etc. Alternatively, in some embodiments, there may be one or more actuators present within a computing system performing the method 600. For example, the one or more actuators may be connected to a chassis of the computing system and positioned adjacent to the device under test. Further, the one or more actuators may be usable to physically engage one or more buttons on the device under test (e.g., may cause one or more physical buttons on the device under test to be pressed). For example, the one or more actuators may cause a volume up button to be pressed, a volume down button to be pressed, a power button to be pressed, etc. In embodiments having one or more actuators usable to physically engage one or more buttons on the device under test, the determined instruction provided in block 606 may be usable to cause the actuators to physically engage the one or more buttons on the device under test. As one example, the determined instruction may cause the device under test to be reset (e.g., to undergo a factory reset) or rebooted. As such, the determined instruction may cause one or more actuators of the computing system to physically engage a power button of the device under test. As another example, the determined instruction may cause the device under test to purchase and subsequently download a mobile app (e.g., from an app store). As such, in order to confirm the purchase of the mobile app, the determined instruction may cause one or more actuators of the computing system to physically engage a power button of the device under test repeatedly (e.g., twice) within a short span of time (e.g., within 1 s).

In some embodiments of the method 600, the determined instruction provided in block 606 may be usable to: (i) cause an application on the device under test to be installed, to launch, to quit, or to be moved to a background of the user interface or (ii) address or delete a notification displayed on the user interface.

In some embodiments of the method 600, the computing device may include a processor configured to execute instructions stored on a memory to determine the instruction for the device under test based on the input. The instructions may include instructions in HTTP and JSON. Further, the instructions in HTTP and JSON may be triggered in response to requests received by an API.

In some embodiments of the method 600, the determined instruction provided at block 606 may be usable to interact with the portion of the user interface in the specified way that results in data being extracted from an application, data being entered into an application, a message being composed, a message being read, a message being deleted, an email being composed, an email being read, an email being deleted, a BLUETOOTH connection being enabled, a BLUETOOTH connection being disabled, a WIFI connection being enabled, a WIFI connection being disabled, mobile data usage being enabled, mobile data usage being disabled, or backing up data in the device under test into an external storage or cloud storage.

In some embodiments of the method 600, the computing device may include a wireless connection or a wireline connection to a wide area network and the method 600 may also include the computing device receiving at least a portion of the predefined workflow from an authorized user via the wide area network.

### IV. CONCLUSION

The present disclosure is not to be limited in terms of the particular embodiments described in this application, which are intended as illustrations of various aspects. Many modifications and variations can be made without departing from its scope, as will be apparent to those skilled in the art. Functionally equivalent methods and apparatuses within the scope of the disclosure, in addition to those described herein, will be apparent to those skilled in the art from the foregoing descriptions. Such modifications and variations are intended to fall within the scope of the appended claims.

The above detailed description describes various features and operations of the disclosed systems, devices, and methods with reference to the accompanying figures. The example embodiments described herein and in the figures are not meant to be limiting. Other embodiments can be utilized, and other changes can be made, without departing from the scope of the subject matter presented herein. It will be readily understood that the aspects of the present disclosure, as generally described herein, and illustrated in the figures, can be arranged, substituted, combined, separated, and designed in a wide variety of different configurations.

With respect to any or all of the message flow diagrams, scenarios, and flow charts in the figures and as discussed herein, each step, block, and/or communication can represent a processing of information and/or a transmission of information in accordance with example embodiments. Alternative embodiments are included within the scope of these example embodiments. In these alternative embodiments, for example, operations described as steps, blocks, transmissions, communications, requests, responses, and/or messages can be executed out of order from that shown or discussed, including substantially concurrently or in reverse order, depending on the functionality involved. Further, more or fewer blocks and/or operations can be used with any of the message flow diagrams, scenarios, and flow charts discussed herein, and these message flow diagrams, scenarios, and flow charts can be combined with one another, in part or in whole.

A step or block that represents a processing of information can correspond to circuitry that can be configured to perform the specific logical functions of a herein-described method or technique. Alternatively or additionally, a step or block that represents a processing of information can correspond to a module, a segment, or a portion of program code (including related data). The program code can include one or more instructions executable by a processor for implementing specific logical operations or actions in the method or technique. The program code and/or related data can be stored on any type of computer readable medium such as a storage device including RAM, a disk drive, a solid-state drive, or another storage medium.

The computer readable medium can also include non-transitory computer readable media such as non-transitory computer readable media that store data for short periods of time like register memory and processor cache. The non-transitory computer readable media can further include non-transitory computer readable media that store program code and/or data for longer periods of time. Thus, the non-transitory computer readable media may include secondary or persistent long-term storage, like ROM, optical or magnetic disks, solid-state drives, or compact disc read only memory (CD-ROM), for example. The non-transitory computer readable media can also be any other volatile or non-volatile storage systems. A non-transitory computer readable medium can be considered a computer readable storage medium, for example, or a tangible storage device.

Moreover, a step or block that represents one or more information transmissions can correspond to information transmissions between software and/or hardware modules in the same physical device. However, other information transmissions can be between software modules and/or hardware modules in different physical devices.

The particular arrangements shown in the figures should not be viewed as limiting. It should be understood that other embodiments could include more or less of each element shown in a given figure. Further, some of the illustrated elements can be combined or omitted. Yet further, an example embodiment can include elements that are not illustrated in the figures.

While various aspects and embodiments have been disclosed herein, other aspects and embodiments will be apparent to those skilled in the art. The various aspects and embodiments disclosed herein are for purpose of illustration and are not intended to be limiting, with the true scope being indicated by the following claims.

What is claimed:

1. A system comprising:
a chassis configured to hold a device under test;
a computing device attached to the chassis, and wherein the computing device is configured to:
receive an input indicative of content being displayed on a user interface of the device under test;
determine, according to a predefined workflow, an instruction for the device under test based on the input; and
provide the determined instruction to the device under test, wherein the determined instruction is usable by the device under test to interact with a portion of the user interface in a specified way.

2. The system of claim 1, wherein the device under test comprises a mobile computing device or a tablet computing device.

3. The system of claim 1, wherein the predefined workflow comprises one or more actions defined within a distributed computing system.

4. The system of claim 1, wherein the computing device providing the determined instruction to the device under test comprises transmitting the determined instruction to the device under test over a wired communication channel.

5. The system of claim 4, wherein the wired communication channel comprises one or more universal serial bus (USB) cables.

6. The system of claim 1, further comprising a camera configured to capture an image of the user interface of the device under test, wherein the computing device receiving the input indicative of content being displayed on the user interface of the device under test comprises receiving the image of the user interface of the device under test from the camera.

7. The system of claim 6, wherein the camera is attached to the chassis.

8. The system of claim 1, wherein the computing device receiving the input indicative of content being displayed on the user interface of the device under test comprises receiving the input over a wired communication channel.

9. The system of claim 8, wherein the wired communication channel comprises a high-definition multimedia interface (HDMI) cable coupled to an output of the device under test.

10. The system of claim 1, further comprising a power supply port coupled to the computing device and attached to the chassis, wherein the computing device is configured to receive electrical power from the power supply port when a power supply is connected to the power supply port.

11. The system of claim 10, wherein the power supply port comprises a universal serial bus (USB) port.

12. The system of claim 10, wherein the power supply port is coupled to the device under test, and wherein the device under test is configured to receive electrical power from the power supply port when a power supply is connected to the power supply port.

13. The system of claim 1, wherein the device under test comprises an IPHONE, wherein the system further comprises a LIGHTNING adapter connected to a port of the IPHONE, and wherein the input indicative of content being displayed on a user interface of the device under test is received from the device under test or the determined instruction is provided to the device under test via the LIGHTNING adapter.

14. The system of claim 1, wherein interacting with the portion of the user interface in the specified way comprises a screen touch, a swipe gesture, a keystroke, or a button press.

15. The system of claim 1, wherein interacting with the portion of the user interface in the specified way:
causes an application on the device under test to be installed, to launch, to quit, or to be moved to a background of the user interface; or
addresses or deletes a notification displayed on the user interface.

16. The system of claim 1, wherein the computing device comprises a processor configured to execute instructions stored on a memory to determine the instruction for the device under test based on the input, wherein the instructions comprise instructions in HyperText Transfer Protocol (HTTP) and JavaScript Object Notation (JSON), and wherein the instructions in HTTP and JSON can be triggered in response to requests received by an Application Programming Interface (API).

17. The system of claim 1, wherein interacting with the portion of the user interface in the specified way results in data being extracted from an application, data being entered into an application, a message being composed, a message being read, a message being deleted, an email being composed, an email being read, an email being deleted, a BLUETOOTH connection being enabled, a BLUETOOTH connection being disabled, a WIFI connection being enabled, a WIFI connection being disabled, mobile data usage being enabled, mobile data usage being disabled, or backing up data in the device under test into an external storage or cloud storage.

18. The system of claim 1, wherein the computing device comprises a wireless connection or a wireline connection to a wide area network, and wherein the computing device is configured to receive at least a portion of the predefined workflow from an authorized user via the wide area network.

19. A method comprising:
receiving, by a computing device, an input indicative of content being displayed on a user interface of a device under test, wherein the device under test is held by a chassis, and wherein the computing device is attached to the chassis;
determining, by the computing device according to a predefined workflow, an instruction for the device under test based on the input; and
providing, by the computing device, the determined instruction to the device under test, wherein the determined instruction is usable by the device under test to interact with a portion of the user interface in a specified way.

20. A non-transitory, computer-readable medium having instructions stored thereon, wherein the instructions are executable by a processor to perform a method comprising:
determining, according to a predefined workflow, an instruction for a device under test based on an input indicative of content being displayed on a user interface of the device under test, wherein the input indicative of content being displayed on the user interface of the device under test is receivable by the processor, and wherein the non-transitory, computer-readable medium and the processor are attachable to a chassis configured to hold the device under test; and
providing the determined instruction to the device under test, wherein the determined instruction is usable by the device under test to interact with a portion of the user interface in a specified way.
